(19) United States
(12) Patent Application Publication
(10) Pub. No.: US 2013/0323874 A1
(43) Pub. Date: Dec. 5, 2013

(54) MANUFACTURE OF SOLAR CELL MODULE

(71) Applicant: SHIN-ETSU CHEMICAL CO., LTD., Tokyo (JP)

(72) Inventors: Tomoyoshi Furihata, Annaka-shi (JP); Atsuo Ito, Annaka-shi (JP); Hiroto Ohwada, Annaka-Shi (JP); Hyung-Bae Kim, Annaka-shi (JP); Naoki Yamakawa, Annaka-shi (JP)

(21) Appl. No.: 13/904,569

(22) Filed: May 29, 2013

(30) Foreign Application Priority Data
May 29, 2012 (JP) 2012-121475

(51) Int. Cl. H01L 31/18

(52) U.S. Cl. CPC H01L 31/18
USPC 438/64

(57) ABSTRACT

A solar cell module is manufactured by coating and curing a curable silicone gel composition onto one surface of each of two panels except a peripheral region to form a cured silicone gel coating, providing a seal member (3) on the peripheral region of one panel (1a), placing a solar cell component (4) on the cured silicone gel coating on one panel, placing the other panel (1b) on the one panel so that the seal member (3) abuts against the peripheral region of the other panel, and the solar cell component is sandwiched between the panels, and heat pressing the panels (1a, 1b) in vacuum for encapsulating the solar cell component (4).

### CROSS-REFERENCE TO RELATED APPLICATION

This non-provisional application claims priority under 35 U.S.C. §119(a) on Patent Application No. 2012-121475 filed in Japan on May 29, 2012, the entire contents of which are hereby incorporated by reference.

### TECHNICAL FIELD

This invention relates to a method for manufacturing a solar cell module by encapsulating a solar cell component with resin.

### BACKGROUND ART

To provide solar cell modules with enhanced conversion efficiency and long-term reliability over 20 to 30 years or even longer, a number of reports and proposals relating to encapsulants were made in the art. From the standpoint of efficiency enhancement, the silicone material is reported to be superior in internal quantum efficiency due to light transmittance at wavelength of about 300 to 400 nm, as compared with the ethylene-vinyl acetate copolymer (EVA) which is currently the mainstream of encapsulant (see Non-Patent Document 1, for example). In fact, an experiment to compare the output power of solar modules using EVA and silicone material as encapsulant is reported (see Non-Patent Document 2, for example).

Originally, the use of silicone material as encapsulant was already implemented in the early period of 1970s when solar cell modules for spacecraft were fabricated. Historically, in the stage when solar cell modules for ground applications are manufactured, the silicone material was replaced by EVA because the silicone material had outstanding problems including material cost and workability for encapsulation whereas the EVA was inexpensive and supplied in film form. Recently, the efficiency enhancement and long-term reliability of solar cells are highlighted again. Accordingly, the properties of silicone material as encapsulant, for example, low modulus, high transparency and weather resistance are considered valuable again. Several encapsulating methods using silicone material are newly proposed.

For example, Patent Document 1 discloses encapsulation using a sheet of organopolysiloxane-based hot melt material. However, it is difficult to work the polysiloxane into a sheet while maintaining high transparency. When the polysiloxane is shaped into a sheet of about 1 mm thick, for example, only a particular shaping technique such as casting or pressing is applicable due to the “brittleness” of the material. This shaping technique is unsuitable for mass-scale production. To ameliorate the brittleness, a filler may be admixed with the polysiloxane. Filler loading can improve moldability at the sacrifice of transparency. Patent Document 2 discloses that interconnected solar cells are positioned on or in a liquid silicone material coated on a substrate, using a multi-axis robot. The liquid silicone material is then cured, thereby achieving encapsulation without trapping air bubbles. Further, Patent Document 3 proposes that a solar cell is placed in vacuum, and the components are compressed using a cell press having a movable plate, thereby achieving encapsulation without trapping air bubbles. In these patent documents, however, no reference is made to the treatment of the solar cell module at its edge face. When silicone is used, its moisture permeability leaves a concern about the ingress of moisture. Since either of these methods differs significantly from the conventional methods of encapsulating solar cells, there is a possibility that the currently available mass-production systems cannot be used.

Patent Document 4 discloses a method of sealing a solar cell module by placing a sealing compound, a solar cell element, and a liquid silicone material on a glass substrate, then laying a back side protection substrate thereon to form a precursory laminate, and compression bonding the laminate in vacuum at room temperature. This method may be difficult to apply to the manufacture of solar cell modules of practical size.

Also, Patent Document 5 discloses a method of sealing a double glazed unit or solar cell panel by placing a sealing composition between peripheral bands of glass pieces in thickness direction, placing an EVA or similar resin inside the sealing composition, and heat compression bonding in vacuum. With this method, the molten EVA can be squeezed out of the peripheral bands of glass pieces in the heat compression bonding step, interfering with the adhesion of the sealing composition to the glass pieces.

### CITATION LIST

Patent Document 1: JP-A 2009-515365 (US 20080276983)
Patent Document 2: JP-A 2007-527109 (US 20060207646)
Patent Document 3: JP-A 2011-514680 (US 20110061724)
Patent Document 4: WO 2009/091068 (US 20100275992)
Patent Document 5: JP-A 2011-231309
Non-Patent Document 1: S. Ohl, G. Hahn, “Increased internal quantum efficiency of encapsulated solar cell by using two-component silicone as encapsulant material”, Proc. 23rd, EU PVSEC, Valencia (2008), pp. 2693-2697
Non-Patent Document 2: Barry Ketola, Chris Shirk, Phillip Griffith, Gabriela Bunea, “Demonstration of the benefits of silicone encapsulation of PV modules in a large scale outdoor array”, Dow Corning Corporation

### DISCLOSURE OF INVENTION

An object of the invention is to provide a method for manufacturing a solar cell module by encapsulating a solar cell component between two panels with a curable silicone gel composition, the method enabling to use an existing solar module manufacturing apparatus, avoiding entrainment of air bubbles, and causing no damages to the solar cell component, the resulting solar cell module being fully durable in that any ingress of moisture from side edges of the module is prohibited.

The invention provides a method for manufacturing a solar cell module by encapsulating a semiconductor substrate-based solar cell component between two panels, comprising the steps of:

(i) coating a curable silicone gel composition onto one surface of each panel except a peripheral region thereof and curing the composition to form a cured silicone gel coating having a penetration of 30 to 200 as measured according to JIS K2220,

(ii) providing a seal member on the peripheral region of the one surface of one panel where the cured silicone gel coating is not formed, said seal member being made of a butyl rubber-based thermoplastic sealing material and being thicker than the cured silicone gel coating, and placing the solar cell component on the cured silicone gel coating,

(iii) placing the other panel on the one panel while the cured silicone gel coating on the other panel facing the solar cell component so that the seal member abuts against the peripheral region of the one surface of the other panel where the cured silicone gel coating is not formed, and the solar cell component is sandwiched between the cured silicone gel coatings on the panels, and

(iv) pressing the two panels together while heating in vacuum for thereby encapsulating the solar cell component.

In a preferred embodiment, the curable silicone gel composition comprises

(A) 100 parts by weight of an organopolysiloxane containing at least one silicon-bonded alkenyl group per molecule, represented by the average compositional formula (1):

RₐR¹_{b}SiO_{(4-a-b)/2} (1)

wherein R is alkenyl, R¹ is a substituted or unsubstituted monovalent hydrocarbon group of 1 to 10 carbon atoms free of aliphatic unsaturation, a is a positive number of 0.0001 to 0.2, b is a positive number of 1.7 to 2.2, and the sum a+b is 1.9 to 2.4,

(B) an organohydrogenpolysiloxane containing at least two silicon-bonded hydrogen atoms per molecule, in such an amount as to give 0.3 to 2.5 moles of silicon-bonded hydrogen per mole of silicon-bonded alkenyl in component (A), and

(C) a catalytic amount of an addition reaction catalyst.

Typically the organohydrogenpolysiloxane (B) has an average degree of polymerization of 40 to 400. The cured silicone gel coating preferably has a thickness of 200 to 1,000 μm.

In a preferred embodiment, step (ii) includes pre-forming the seal member in tape or string form from the butyl rubber-based thermoplastic sealing material and extending the seal member on the peripheral region of the one surface of one panel where the cured silicone gel coating is not formed.

In a preferred embodiment, step (iv) includes heating the panels at 100 to 150° C. in vacuum. Most often, step (iv) is carried out using a vacuum laminator.

Typically, the two panels are colorless tempered glass plates.

### ADVANTAGEOUS EFFECTS OF INVENTION

According to the invention, a solar cell component is sandwiched between cured silicone gel coatings on two panels in vacuum, the cured silicone gel coatings having a specific penetration, before the assembly is compressed. The solar cell component can be encapsulated without entraining air bubbles and without causing damage to the solar cell component. A seal member of butyl rubber-based thermoplastic sealing material is disposed on the peripheral region of the panel surface where the cured silicone gel coating is not formed, and the two panels are then heated and pressed. As a result, the seal member is bonded to the panels so as to surround the inside cured silicone gel coatings in a tight seal manner, preventing any ingress of moisture and gases through the side edges of the module. The resulting solar cell module is fully durable. The inventive method can be implemented using the existing solar module manufacturing apparatus used with EVA-encapsulated modules, typically vacuum laminator. Thus, solar modules can be manufactured without a need for a newly designed lamination apparatus.

At the future stage when the thickness of solar cell components is reduced below 100 μm, such thin solar components can be laminated into modules while encapsulating them with cured silicone gel coatings featuring low modulus, low hardness and weather resistance. The resulting solar cell modules have higher photovoltaic conversion efficiency and maintain long-term reliability.

### BRIEF DESCRIPTION OF DRAWINGS

FIG. 1 is a cross-sectional view of two panels having a cured silicone gel coating formed thereon.

FIG. 2 is a cross-sectional view of one panel wherein a seal member is provided on a peripheral region thereof and a solar cell component is rested on the cured silicone gel coating.

FIG. 3 is a cross-sectional view of an assembly constructed by placing the other panel on the one panel so as to sandwich the solar cell component therebetween.

FIG. 4 is a cross-sectional view of the panel assembly which is compression bonded by a vacuum laminator.

FIG. 5 is a cross-sectional view of a solar cell module after frame mounting.

### DESCRIPTION OF PREFERRED EMBODIMENTS

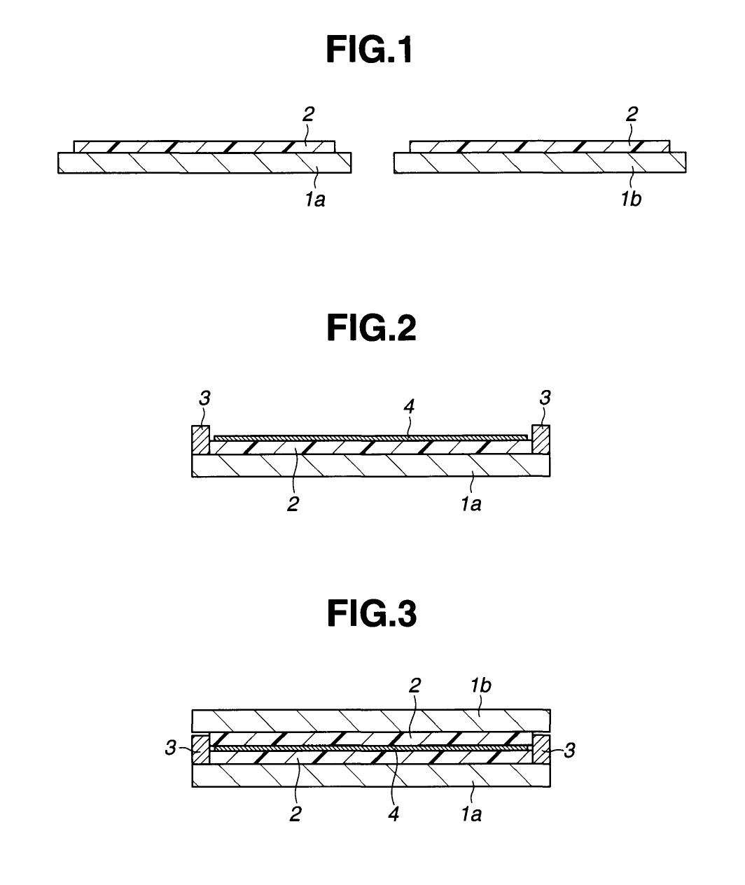

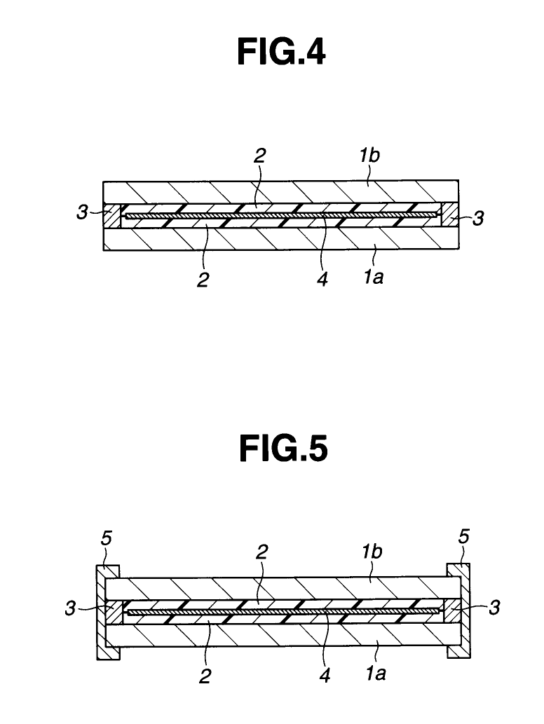

The method for manufacturing a solar cell module according to the invention is described by referring to the illustrated preferred embodiment. FIG. 1 is a cross-sectional view of two panels 1a, 1b on which a curable silicone gel composition 2 is coated and cured. FIG. 2 is a cross-sectional view of one panel 1a wherein a solar cell component 4 is rested on the cured silicone gel coating 2 and a seal member 3 is provided upright on a peripheral region of the panel surface where the cured silicone gel coating is not formed. FIG. 3 is a cross-sectional view of an assembly constructed by placing the other panel 1b on the one panel 1a of FIG. 2, with the cured silicone gel coatings 2, 2 faced inward. FIG. 4 is a cross-sectional view of the panel assembly obtained by vacuum laminating the two panels 1a, 1b of FIG. 3. FIG. 5 is a cross-sectional view of a solar cell module in which the side edges of two panels 1a, 1b are secured by a frame member 5.

### (i) Step of Forming Cured Silicone Gel Coating (FIG. 1)

First of all, as shown in FIG. 1, a curable silicone gel composition is coated onto one surface of each of two panels 1a and 1b, which are transparent members, and cured to form a cured silicone gel coating 2 thereon.

In the illustrated embodiment using two panels, one panel 1a is a transparent member serving as sunlight incident side, which must remain reliable in such properties as transparency, weather resistance and shock resistance for extended periods in outdoor applications. It may be made of colorless tempered glass, acrylic resin, fluoro-resin or polycarbonate resin, for example. Most often, glass plates, typically colorless tempered glass plates of about 3 to 5 mm thick are used.

The other panel 1b is disposed remote from the sunlight-incident side and opposed to the one panel 1a. The other panel 1b is required to dissipate the heat of the solar cell component efficiently. It may be made of glass, synthetic resin, metal and composite materials. Exemplary glass materials include float glass (green in hue), colorless glass and tempered glass. Exemplary synthetic resins include acrylic resins, polycarbonate (PC) resins, polyethylene terephthalate (PET) resins, and epoxy resins. Exemplary metal materials include copper, aluminum and iron. Exemplary composite materials include synthetic resins loaded with high heat conductivity fillers such as silica, titania, alumina and aluminum nitride.

If the other panel 1b disposed remote from the sunlight-incident side is a transparent member like one panel 1a on which sunlight is incident, parts of incident sunlight and scattering light may be transmitted to the remote side. Then in an example where the solar cell module is installed in a grassland, part of sunlight reaches the area of the land which is disposed below and shaded by the module, so that plants can grow even in the otherwise shaded area. This is convenient in that the module-installed region can also be utilized for pasturage.

The cured silicone gel coating 2 must remain reliable in outdoor service for a long term of over 20 years with respect to its properties including transparency and weather resistance. In this sense, the cured silicone gel coating 2 must meet UV resistance, low modulus, and good adhesion to panels 1a, 1b.

The cured silicone gel coating 2 is formed of the curable silicone gel composition. The crosslinking mode of the silicone composition may be any of the moisture cure, UV cure, organic peroxide cure, and addition cure catalyzed by platinum. Preferably an addition cure silicone composition is used because of no cure by-products and little discoloration.

The curable silicone gel composition used herein is preferably defined as comprising the following components:

(A) 100 parts by weight of an organopolysiloxane containing at least one silicon-bonded alkenyl group per molecule, represented by the average compositional formula (1):

RₐR¹_{b}SiO_{(4-a-b)/2} (1)

wherein R is alkenyl, R¹ is a substituted or unsubstituted monovalent hydrocarbon group of 1 to 10 carbon atoms free of aliphatic unsaturation, a is a positive number of 0.0001 to 0.2, b is a positive number of 1.7 to 2.2, and the sum a+b is 1.9 to 2.4,

(B) an organohydrogenpolysiloxane containing at least two silicon-bonded hydrogen atoms per molecule, in such an amount as to give 0.3 to 2.5 moles of silicon-bonded hydrogen per mole of silicon-bonded alkenyl in component (A), and

(C) a catalytic amount of an addition reaction catalyst.

Component (A) serves as a base polymer in the curable silicone gel composition. It is an organopolysiloxane containing at least one silicon-bonded alkenyl group per molecule, represented by the average compositional formula (1).

In formula (1), R is independently an alkenyl group of 2 to 6 carbon atoms, preferably 2 to 4 carbon atoms, and more preferably 2 to 3 carbon atoms. Examples include vinyl, allyl, propenyl, isopropenyl, butenyl, and isobutenyl, with vinyl being most preferred.

R¹ is independently a substituted or unsubstituted monovalent hydrocarbon group free of aliphatic unsaturation, having 1 to 10 carbon atoms, preferably 1 to 6 carbon atoms. Examples of the monovalent hydrocarbon group include straight, branched or cyclic alkyl groups such as methyl, ethyl, propyl, isopropyl, butyl, isobutyl, tert-butyl, pentyl, hexyl, cyclohexyl, octyl and decyl; aryl groups such as phenyl and tolyl; aralkyl groups such as benzyl and phenylethyl; and substituted forms of the foregoing in which some or all hydrogen atoms are substituted by halogen (e.g., chloro, bromo or fluoro) such as chloromethyl and 3,3,3-trifluoropropyl. Of these, methyl, phenyl and 3,3,3-trifluoropropyl are preferred for ease of synthesis. Inter alia, methyl is most preferred in view of UV resistance.

The subscript “a” is a positive number of 0.0001 to 0.2, preferably 0.0005 to 0.1; b is a positive number of 1.7 to 2.2, preferably 1.9 to 2.02. The sum a+b is in a range from 1.9 to 2.4, preferably from 1.95 to 2.05.

The organopolysiloxane should contain at least one silicon-bonded alkenyl group per molecule, preferably at least two, more preferably 2 to 50, and even more preferably 2 to 10 silicon-bonded alkenyl groups per molecule. The values of a and b may be selected so as to meet the requirement of silicon-bonded alkenyl group.

The molecular structure of the organopolysiloxane is not particularly limited. It may have a linear structure or a branched structure containing such units as RSiO_{3/2}, R¹SiO_{3/2}, and SiO₂ units wherein R and R¹ are as defined above. Preferred is an organopolysiloxane having the general formula (1a), that is, a substantially linear diorganopolysiloxane having a backbone consisting essentially of recurring diorganosiloxane units and terminated with a triorganosiloxy group at either end of the molecular chain.

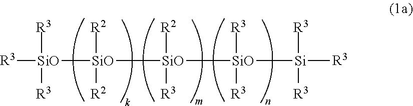

Herein R² is independently a substituted or unsubstituted monovalent hydrocarbon group free of aliphatic unsaturation; R³ is independently a substituted or unsubstituted monovalent hydrocarbon group free of aliphatic unsaturation or an alkenyl group, with the proviso that at least one, preferably at least two R³ are alkenyl; where either one of R³ at opposite ends of the molecular chain is alkenyl, k is an integer of 40 to 1,200, m is an integer of 0 to 50, and n is an integer of 0 to 50; where none of R³ at opposite ends of the molecular chain are alkenyl, k is an integer of 40 to 1,200, m is an integer of 1 to 50, and n is an integer of 0 to 50; and the sum m+n is at least 1.

In formula (1a), R² is independently a substituted or unsubstituted monovalent hydrocarbon group free of aliphatic unsaturation, having 1 to 10 carbon atoms, preferably 1 to 6 carbon atoms. Examples are as exemplified for R¹ in formula (1). Inter alia, methyl, phenyl and 3,3,3-trifluoropropyl are preferred for ease of synthesis.

Also R³ is independently a substituted or unsubstituted monovalent hydrocarbon group free of aliphatic unsaturation, having 1 to 10 carbon atoms, preferably 1 to 6 carbon atoms. Examples are as exemplified for R¹ in formula (1). Inter alia, methyl, phenyl and 3,3,3-trifluoropropyl are preferred for ease of synthesis. Alternatively, R³ is an alkenyl group of 2 to 6 carbon atoms, preferably 2 to 4 carbon atoms, and more preferably 2 to 3 carbon atoms. Examples include vinyl, allyl, propenyl, isopropenyl, butenyl, and isobutenyl, with vinyl being most preferred.

In formula (1a), where either one of R³ at opposite ends of the molecular chain is alkenyl, k is an integer of 40 to 1,200, m is an integer of 0 to 50, and n is an integer of 0 to 50, and preferably k is an integer of 100 to 1,000, m is an integer of 0 to 40, and n is 0. Where none of R³ at opposite ends of the molecular chain are alkenyl, k is an integer of 40 to 1,200, m is an integer of 1 to 50, and n is an integer of 0 to 50, and preferably k is an integer of 100 to 1,000, m is an integer of 2 to 40, and n is 0.

Examples of the organopolysiloxane of formula (1a) include, but are not limited to, both end dimethylvinylsiloxy-terminated dimethylpolysiloxane, both end dimethylvinylsiloxy-terminated dimethylsiloxane/methylvinylsiloxane copolymers, both end dimethylvinylsiloxy-terminated dimethylsiloxane/diphenylsiloxane copolymers, both end dimethylvinylsiloxy-terminated dimethylsiloxane/-methylvinylsiloxane/diphenylsiloxane copolymers, both end dimethylvinylsiloxy-terminated methyltrifluoropropylpolysiloxane, both end dimethylvinylsiloxy-terminated dimethylsiloxane/methyltrifluoropropylsiloxane copolymers, both end dimethylvinylsiloxy-terminated dimethylsiloxane/-methyltrifluoropropylsiloxane/methylvinylsiloxane copolymers, both end trimethylsiloxy-terminated dimethylsiloxane/vinylmethylsiloxane copolymers, both end trimethylsiloxy-terminated dimethylsiloxane/-vinylmethylsiloxane/diphenylsiloxane copolymers, both end trimethylsiloxy-terminated vinylmethylsiloxane/methyltrifluoropropylsiloxane copolymers, trimethylsiloxy and dimethylvinylsiloxy-terminated dimethylpolysiloxane, trimethylsiloxy and dimethylvinylsiloxy-terminated dimethylsiloxane/methylvinylsiloxane copolymers, trimethylsiloxy and dimethylvinylsiloxy-terminated dimethylsiloxane/diphenylsiloxane copolymers, trimethylsiloxy and dimethylvinylsiloxy-terminated dimethylsiloxane/diphenylsiloxane/methylvinylsiloxane copolymers, trimethylsiloxy and dimethylvinylsiloxy-terminated methyltrifluoropropylpolysiloxane, trimethylsiloxy and dimethylvinylsiloxy-terminated dimethylsiloxane/methyltrifluoropropylsiloxane copolymers, trimethylsiloxy and dimethylvinylsiloxy-terminated dimethylsiloxane/methyltrifluoropropylsiloxane/methylvinylsiloxane copolymers, both end methyldivinylsiloxy-terminated dimethylpolysiloxane, both end methyldivinylsiloxy-terminated dimethylsiloxane/methylvinylsiloxane copolymers, both end methyldivinylsiloxy-terminated dimethylsiloxane/diphenylsiloxane copolymers, both end methyldivinylsiloxy-terminated dimethylsiloxane/-methylvinylsiloxane/diphenylsiloxane copolymers, both end methyldivinylsiloxy-terminated methyltrifluoropropylpolysiloxane, both end methyldivinylsiloxy-terminated dimethylsiloxane/methyltrifluoropropylsiloxane copolymers, both end methyldivinylsiloxy-terminated dimethylsiloxane/-methyltrifluoropropylsiloxane/methylvinylsiloxane copolymers, both end trivinylsiloxy-terminated dimethylpolysiloxane, both end trivinylsiloxy-terminated dimethylsiloxane/methylvinylsiloxane copolymers, both end trivinylsiloxy-terminated dimethylsiloxane/diphenylsiloxane copolymers, both end trivinylsiloxy-terminated dimethylsiloxane/-methylvinylsiloxane/diphenylsiloxane copolymers, both end trivinylsiloxy-terminated methyltrifluoropropylpolysiloxane, both end trivinylsiloxy-terminated dimethylsiloxane/methyltrifluoropropylsiloxane copolymers, and both end trivinylsiloxy-terminated dimethylsiloxane/-methyltrifluoropropylsiloxane/methylvinylsiloxane copolymers.

Although the viscosity of the organopolysiloxane (A) is not particularly limited, it preferably has a viscosity at 25° C. in the range of 50 to 100,000 mPa-s, more preferably 100 to 10,000 mPa-s for ease of handling and working of the composition and the strength and flow of cured gel. Notably, the viscosity is measured at 25° C. by a rotational viscometer.

Component (B) functions as a crosslinker by reacting with component (A). It is an organohydrogenpolysiloxane containing at least two silicon-bonded hydrogen atoms (i.e., hydrosilyl or SiH groups) per molecule. The organohydrogenpolysiloxane contains preferably 2 to 30, more preferably 2 to 10, and even more preferably 2 to 5 SiH groups per molecule.

In the organohydrogenpolysiloxane, hydrogen may be attached to the silicon at the end and/or an intermediate position of the molecular chain. Its molecular structure is not particularly limited and may be linear, cyclic, branched or three-dimensional network (or resinous).

In the organohydrogenpolysiloxane, the number of silicon atoms per molecule, that is, average degree of polymerization is typically 20 to 1,000. For ease of handling and working of the composition and better properties (e.g., low modulus and low stress) of cured gel, the number of silicon atoms per molecule is preferably 40 to 1,000, more preferably 40 to 400, even more preferably 60 to 300, further preferably 100 to 300, and most preferably 160 to 300. As used herein, the average degree of polymerization is determined versus polystyrene standards by gel permeation chromatography (GPC) using toluene as solvent.

Typically the organohydrogenpolysiloxane has a viscosity at 25° C. of 10 to 100,000 mPa-s, preferably 20 to 10,000 mPa-s, and more preferably 50 to 5,000 mPa-s. An organohydrogenpolysiloxane which is liquid at room temperature (25° C.) is preferred.

The organohydrogenpolysiloxane preferably has the average compositional formula (2):

R⁴_{c}H_{d}SiO_{(4-c-d)/2} (2)

wherein R⁴ is each independently a substituted or unsubstituted monovalent hydrocarbon group free of aliphatic unsaturation, c is a positive number of 0.7 to 2.2, d is a positive number of 0.001 to 0.5, and the sum c+d is 0.8 to 2.5.

In formula (2), R⁴ is independently a substituted or unsubstituted monovalent hydrocarbon group free of aliphatic unsaturation, having 1 to 10 carbon atoms, preferably 1 to 6 carbon atoms. Examples of the monovalent hydrocarbon group include straight, branched or cyclic alkyl groups such as methyl, ethyl, propyl, isopropyl, butyl, isobutyl, tert-butyl, pentyl, neopentyl, hexyl, cyclohexyl, octyl, nonyl, and decyl; aryl groups such as phenyl, tolyl, xylyl and naphthyl; aralkyl groups such as benzyl, phenylethyl and phenylpropyl; and substituted forms of the foregoing in which some or all hydrogen atoms are substituted by halogen (e.g., chloro, bromo or fluoro) such as 3,3,3-trifluoropropyl. Of these, alkyl, aryl and 3,3,3-trifluoropropyl groups are preferred, and methyl, phenyl and 3,3,3-trifluoropropyl are most preferred.

The subscript c is a positive number of 0.7 to 2.2, preferably 1.0 to 2.1; d is a positive number of 0.001 to 0.5, preferably 0.001 to 0.1, and more preferably 0.005 to 0.1, even more preferably 0.005 to 0.05, and most preferably 0.005 to 0.03; and the sum c+d is in a range of 0.8 to 2.5, preferably 1.0 to 2.5, and more preferably 1.5 to 2.2.

Examples of the organohydrogenpolysiloxane having formula (2) include, but are not limited to, methylhydrogensiloxane/dimethylsiloxane cyclic copolymers, both end trimethylsiloxy-terminated methylhydrogenpolysiloxane, both end trimethylsiloxy-terminated dimethylsiloxane/methylhydrogensiloxane copolymers, both end dimethylhydrogensiloxy-terminated dimethylpolysiloxane, both end dimethylhydrogensiloxy-terminated dimethylsiloxane/methylhydrogensiloxane copolymers, both end trimethylsiloxy-terminated methylhydrogensiloxane/diphenylsiloxane copolymers, both end trimethylsiloxy-terminated methylhydrogensiloxane/-diphenylsiloxane/dimethylsiloxane copolymers, both end dimethylhydrogensiloxy-terminated methylhydrogen-siloxane/dimethylsiloxane/diphenylsiloxane copolymers, copolymers consisting of (CH₃)₂HSiO_{1/2}, (CH₃)₃SiO_{1/2} and SiO_{4/2} units,

copolymers consisting of (CH₃)₂HSiO_{1/2} and SiO_{4/2} units, and copolymers consisting of (CH₃)₂HSiO_{1/2}, (C₆H₅)SiO_{3/2} and SiO_{4/2} units.

An appropriate amount of component (B) used is at least 1 part, preferably at least 3 parts by weight per 100 parts by weight the component (A). When the upper limit is taken into account, an appropriate amount of component (B) used is 15 to 500 parts, more preferably 20 to 500 parts, and even more preferably 30 to 200 parts by weight per 100 parts by weight the component (A). In addition to the above requirement, component (B) should be used in such amounts as to give 0.3 to 2.5 moles, preferably 0.5 to 2 moles, and more preferably 0.6 to 1.5 moles of silicon-bonded hydrogen per mole of silicon-bonded alkenyl groups in component (A). If the amount of component (B) is less than 1 part by weight, the cured product is likely to oil bleeding. An SiH/alkenyl molar ratio of less than 0.3/1 may provide an insufficient crosslinking density, indicating that the composition may not be fully cured or if cured, the cured product may have poor heat resistance. An SiH/alkenyl molar ratio of more than 2.5/1 may give rise to problems including bubbling due to dehydrogenation reaction, poor heat resistance and oil bleeding of the cured product.

Component (C) is a catalyst for promoting addition reaction between silicon-bonded alkenyl groups in component (A) and silicon-bonded hydrogen atoms (i.e., SiH groups) in component (B). The catalyst is typically a platinum group metal based catalyst which is selected from many well-known catalysts. Examples include platinum black, chloroplatinic acid, alcohol-modified products of chloroplatinic acid, and complexes of chloroplatinic acid with olefins, aldehydes, vinylsiloxanes or acetylene alcohols.

The catalyst is added in a catalytic amount, which may be properly determined depending on the desired cure rate. The catalyst is typically added in such amounts as to give 0.1 to 1,000 ppm, preferably 1 to 300 ppm of platinum atom based on the total weight of components (A) and (B). If the amount of the catalyst is too much, the cured product may have poor heat resistance.

The curable silicone gel composition may be prepared by mixing the foregoing components (A) to (C) and optional components (if used) in a standard way. Upon formulation, the composition may be divided into two or multiple parts, if desired. For example, the composition is divided into one part composed of a portion of component (A) and component (C), and another part composed of the remainder of component (A) and component (B), and these two parts are mixed together on use.

The curable silicone gel composition thus obtained is coated onto one surface of each of panel 1a which is a transparent member on the sunlight incident side and panel 1b which is disposed remote from the sunlight incident side, and cured to form a cured silicone gel coating 2.

### Coating Step

On coating, any of standard techniques such as spray coating, curtain coating, knife coating, screen coating, and combinations thereof may be used. The coating weight is preferably adjusted such that the silicone gel coating 2 as cured may have a thickness of 200 to 1,000 μm, more preferably 300 to 800 μm. If the coating thickness is less than 200 μm, the following problems may arise. The advantageous properties of silicone gel including low modulus and low hardness are not fully available. In the step of sandwiching a semiconductor substrate-based solar cell component between panels, the coating allows the solar cell component to be cracked. In an outdoor environment where temperature fluctuates, the coating fails to accommodate differences in coefficient of linear expansion and modulus from the electrical connection on the solar cell component surface, allowing the solar cell component to become brittle. If the coating thickness exceeds 1,000 μm, a longer time is taken for curing and an increased amount of the curable silicone gel composition coated adds to the expense.

Curing Step After panels 1a, 1b are coated with the curable silicone gel composition, it is cured at 80 to 150° C. for 5 to 30 minutes in a conventional manner to form a cured silicone gel coating 2 on each panel 1a, 1b.

The cured silicone gel coating 2 thus formed should have a penetration of 30 to 200, preferably 40 to 150, as measured according to JIS K2220 using ¼ cone. If the penetration of a coating is less than 30, the following problems may arise. The advantageous properties of cured silicone gel including low modulus and low hardness are not fully available. In the step of sandwiching a semiconductor substrate-based solar cell component between panels, the coating allows the solar cell component to be cracked. In an outdoor environment where temperature fluctuates, the coating fails to accommodate differences in coefficient of linear expansion and modulus from the electrical connection on the solar cell component surface, allowing the solar cell component to become brittle. If the penetration of a coating exceeds 200, the cured silicone gel coating may flow, failing to retain its shape.

When one surface of each panel 1a, 1b is coated with the silicone gel composition, a peripheral region of the panel surface (to be covered with cured silicone gel coating), for example, a peripheral band (like a molding of a picture frame) having a width of 5 to 20 mm should be left uncoated. In the next step, a seal member of butyl rubber-based thermoplastic sealing material is disposed on this uncoated region. If the silicone gel composition is present, even slightly, on the peripheral region of the panel surface, it adversely affects the adhesion between the seal member and the panel, and moisture can ingress through such defective bonds to threaten the long-term reliability of the solar cell module. Therefore, the peripheral region of the panel surface is masked with masking tape (like a frame molding) before the curable silicone gel composition is coated to the panel surface. Then the composition does not stick to the peripheral region.

### (ii) Step of Placing Seal Member and Solar Cell Component (FIG. 2)

Next, as shown in FIG. 2, a seal member 3 of a butyl rubber-based thermoplastic sealing material which is thicker than the cured silicone gel coating 2 is provided on the peripheral region of the one surface of one panel 1a where the cured silicone gel coating 2 is not formed, and a solar cell component 4 is placed on the cured silicone gel coating 2.

The seal member 3 is made of a butyl rubber-based thermoplastic sealing material, which may be any of commercially available butyl rubber-based sealing materials. Since the subsequent step of vacuum lamination applies heat at a temperature of 100 to 150° C., a sealing material of hot melt type capable of retaining its shape in that temperature range is preferred. A suitable hot melt sealing material is available under the trade name Hot Melt M-155P (adhesive for solar modules) from Yokohama Rubber Co., Ltd.

The seal member 3 may be provided by any desired ways. Using a hot-melt applicator, for example, the butyl rubber-based thermoplastic sealing material is coated to the peripheral region of the one surface of one panel 1a where the cured silicone gel coating 2 is not formed. Alternatively, the butyl rubber-based thermoplastic sealing material is previously shaped as a piece of tape or string, which is extended on the peripheral region.

The solar cell component 4 may comprise a solar or photovoltaic cell constructed using a silicon material (or silicon substrate) selected from monocrystalline silicon and multicrystalline silicon or both. Most often, the solar cell component 4 is a cell string comprising 2 to 60 solar cells electrically series connected via interconnectors such as tab wires. The solar cell is preferably of double side light-receiving type. In this case, both panels 1a and 1b are transparent.

In step (ii), as shown in FIG. 2, the seal member 3 is provided (like a frame molding) on the peripheral region of the surface of one panel 1a where the cured silicone gel coating 2 is not formed, before the solar cell component 4 with its incident side facing downward (toward panel 1a) is placed on the cured silicone gel coating 2. In an alternative embodiment, step (ii) may be applied to the other panel 1b which is disposed remote from the sunlight-incident side. In the alternative embodiment, the seal member 3 is provided (like a frame molding) on the peripheral region of the surface of other panel 1b where the cured silicone gel coating 2 is not formed, before the solar cell component 4 with its incident side facing upward (opposite to panel 1b) is placed on the cured silicone gel coating 2. In either embodiment, the solar cell component 4 may be placed on the cured silicone gel coating 2 so as to leave therebetween a narrow space (not shown) which can be evacuated when pumped to vacuum by a vacuum laminator in the subsequent step.

(iii) Step of Sandwiching Solar Cell Component Between Panels (FIG. 3)

Next, as shown in FIG. 3, the other panel 1b is placed on the one panel 1a while the cured silicone gel coating 2 on the other panel 1b facing the solar cell component 4 on the cured silicone gel coating 2 on the one panel 1a so that the seal member 3 abuts against the peripheral region of the one surface of the other panel 1b where the cured silicone gel coating 2 is not formed, and the solar cell component 4 is sandwiched between the cured silicone gel coatings 2 on the panels 1a, 1b. At this point, the other panel 1b is physically supported by the seal member 3, but a gap is left between the seal member 3 and panel 1b that can provide fluid communication between the exterior of panel 1b and any space between panels 1a, 1b. Also, the solar cell component 4 disposed on the cured silicone gel coating 2 on one panel 1a is spaced apart from the cured silicone gel coating 2 on the other panel 1b. This placement step may be carried out within the confines of a vacuum laminator to be described later.

### (iv) Step of Vacuum Lamination (FIG. 4)

Next, the precursory laminate or assembly of solar cell component 4 sandwiched between two panels 1a, 1b as shown in FIG. 3 is vacuum laminated. Specifically, using a vacuum laminator (not shown), two panels 1a, 1b are pressed together while heating in vacuum, for thereby encapsulating the solar cell component 4, as shown in FIG. 4.

The vacuum laminator used herein may be a laminator comprising two adjacent vacuum tanks partitioned by a flexible membrane, as commonly used in the manufacture of solar cell modules. For example, the precursory assembly of panels 1a, 1b as shown in FIG. 3 is set in one tank, two tanks are pumped to vacuum, so that a substantial vacuum is established between panels 1a and 1b. At the same time, at least outer portions of panels 1a, 1b are heated. Thereafter, while the one tank having the precursory assembly of panels 1a, 1b set therein is kept in vacuum, the other tank is released to atmospheric pressure or even kept under an applied pressure, whereby the panels 1a, 1b are compressed in their thickness direction by the membrane. For example, the panels 1a, 1b are compressed for 1 to 5 minutes while heating at 100 to 150° C. Then the seal member 3 is tightly bonded to panels 1a, 1b.

Since the cured silicone gel coatings 2 on panels 1a, 1b are pressed to each other in vacuum, as shown in FIG. 4, the cured silicone gel coatings 2 are closely bonded and merged into an integral encapsulant layer without trapping air bubbles. Since the cured silicone gel coatings 2 have a specific penetration, the solar cell component 4 is embedded in the encapsulant layer without failures. Since a pressure acting in a direction to press panels 1a, 1b is applied to the seal member 3 which is heated at the predetermined temperature, the seal member 3 tightly seals the peripheral region of the surface of panels 1a, 1b and the peripheral edges of the cured silicone gel coatings 2 and bonds to the panels 1a, 1b. As a result, the seal member 3 tightly encloses the cured silicone gel coatings 2 together with two panels 1a, 1b, preventing the ingress of moisture and gas into the solar cell module from its edge faces. The resulting solar cell module is thus of fully durable performance.

### (v) Step of Framing (FIG. 5)

As shown in FIG. 5, a frame member 5 is mounted on the outer periphery of the panels 1a, 1b as press bonded, completing a solar cell module.

The frame member 5 is preferably made of aluminum alloy, stainless steel or similar material having strength against shocks, wind pressure or snow deposition, weather resistance, and lightweight. The frame member 5 of such material is mounted so as to enclose the outer periphery of the assembly of panels 1a, 1b having the solar cell component 4 sandwiched therebetween and fixedly secured to the panels by screws (not shown).

In the solar cell module thus constructed, since the solar cell component 4 is held by flat panels 1a, 1b via cured silicone gel coatings 2, the solar cell module, when considered as a panel, is minimized in variation of light-receiving angle relative to sunlight and thus exerts consistent performance. According to the inventive method, solar cell modules of consistent performance can be easily manufactured in a large scale.

### EXAMPLE

Examples of the invention are given below by way of illustration and not by way of limitation. It is noted that the viscosity is measured at 25° C. by a rotational viscometer. All parts and percents are by weight. Vi stands for vinyl. The panels used in Examples and Comparative Examples are two colorless tempered glass plates of 340 mm×360 mm, which are simply referred to as glass plates.

### Example 1

A silicone gel composition was prepared by mixing 100 parts of both end dimethylvinylsiloxy-terminated dimethylpolysiloxane having a viscosity of 1,000 mPa-s, 63 parts of both end trimethylsiloxy-terminated dimethylsiloxane/methylhydrogensiloxane copolymer represented by the formula (3) and having a viscosity of 1,000 mPa-s (to give 1.05 silicon-bonded hydrogen in component (B) per silicon-bonded alkenyl in component (A), that is, H/Vi ratio=1.05), and 0.05 part of a dimethylpolysiloxane solution of chloroplatinic acid-vinylsiloxane complex (platinum concentration 1%) until uniform.

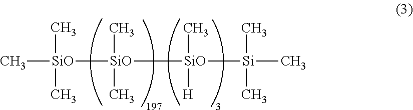

When the composition was cured in an oven at 150° C. for 30 minutes, the cured gel product had a penetration of 70. It is noted that the penetration was measured according to JIS K2220 with a ¼ cone, using an automatic penetrometer RPM-101 by Rigo Co., Ltd.

Each of two glass plates was masked on its peripheral region of 5 mm wide with masking tape. The composition was applied to one surface of each glass plate by knife coating and heated in an oven at 120° C. for 10 minutes to form a cured silicone gel coating having a thickness of 200 μm.

After heat curing, the masking tape was stripped off. A seal member in tape form made of a butyl rubber-based thermoplastic sealing material (hot melt M-155P by Yokohama Rubber Co., Ltd.) was placed on the peripheral region of one glass plate where the masking tape was stripped off. A 2×2 series cell string was rested on the cured silicone gel coating on one glass plate, the cell string being constructed by arranging monocrystalline silicon solar cells in a 2/2 column/row matrix and serially connecting them via interconnectors.

In a vacuum laminator, the other glass plate having the cured silicone gel coating formed thereon was placed on the one glass plate having the cell string rested on its cured silicone gel coating. The glass plates were pressed under atmospheric pressure for 2 minutes while heating the glass plates at 120° C. in vacuum, completing a solar cell module A.

### Example 2

A solar cell module B was manufactured as in Example 1 except that the composition was knife coated to two glass plates and heated in an oven at 120° C. for 10 minutes to form cured silicone gel coatings having a thickness of 500 μm.

### Example 3

A solar cell module C was manufactured as in Example 1 except that the composition was knife coated to two glass plates and heated in an oven at 150° C. for 10 minutes to form cured silicone gel coatings having a thickness of 800 μm.

### Example 4

A silicone gel composition was prepared by mixing 100 parts of both end dimethylvinylsiloxy-terminated dimethylpolysiloxane having a viscosity of 5,000 mPa-s, 25 parts of both end dimethylhydrogensiloxy-terminated dimethylsiloxane/methylhydrogensiloxane copolymer represented by the formula (4) and having a viscosity of 600 mPa-s (to give a H/Vi ratio=1.3), and 0.05 part of a dimethylpolysiloxane solution of chloroplatinic acid-vinylsiloxane complex (platinum concentration 1%) until uniform.

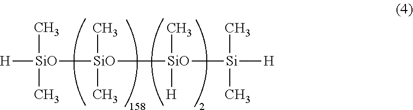

When the composition was cured in an oven at 150° C. for 30 minutes, the cured gel product had a penetration of 40.

The composition was knife coated to one surface of each of two glass plates and heated in an oven at 120° C. for 10 minutes to form a cured silicone gel coating having a thickness of 200 μm.

Aside from using these glass plates having the cured silicone gel coating formed thereon, a solar cell module D was manufactured as in Example 1.

### Example 5

A solar cell module E was manufactured as in Example 4 except that the composition was knife coated to two glass plates and heated in an oven at 120° C. for 10 minutes to form cured silicone gel coatings having a thickness of 500 μm.

### Example 6

A solar cell module E was manufactured as in Example 4 except that the composition was knife coated to two glass plates and heated in an oven at 150° C. for 10 minutes to form cured silicone gel coatings having a thickness of 800 μm.

### Example 7

A silicone gel composition was prepared by mixing 100 parts of both end trimethylsiloxy-terminated dimethylsiloxane/methylvinylsiloxane copolymer represented by the formula (5) and having a viscosity of 1,000 mPa-s, 40 parts of both end dimethylhydrogensiloxy-terminated dimethylpolysiloxane represented by the formula (6) and having a viscosity of 600 mPa-s (to give a H/Vi ratio=0.95), and 0.05 part of a dimethylpolysiloxane solution of chloroplatinic acid-vinylsiloxane complex (platinum concentration 1%) until uniform.

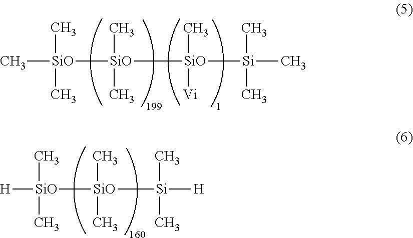

When the composition was cured by heating in an oven at 120° C. for 10 minutes, the cured gel product had a penetration of 120.

The composition was applied to one surface of each of two colorless tempered glass plates of 340 mm×360 mm by knife coating, and heated in an oven at 120° C. for 10 minutes to form a cured silicone gel coating having a thickness of 200 μm.

Aside from using these glass plates having the cured silicone gel coating formed thereon, a solar cell module G was manufactured as in Example 1.

### Example 8

A solar cell module H was manufactured as in Example 7 except that the composition was knife coated to two glass plates and heated in an oven at 120° C. for 10 minutes to form cured silicone gel coatings having a thickness of 500 μm.

### Example 9

A solar cell module I was manufactured as in Example 7 except that the composition was knife coated to two glass plates and heated in an oven at 150° C. for 10 minutes to form cured silicone gel coatings having a thickness of 800 μm.

### Example 10

A solar cell module J was manufactured as in Example 1 aside from the following changes. On one glass plate, the silicone gel composition of Example 1 was knife coated and heated in an oven at 150° C. for 30 minutes to form a cured silicone gel coating having a thickness of 500 μm. This glass plate was used as a panel on the sunlight-incident side. On another glass plate, the silicone gel composition of Example 4 was knife coated and heated in an oven at 120° C. for 10 minutes to form a cured silicone gel coating having a thickness of 500 μm. This glass plate was used as a panel on an opposite side to the sunlight-incident side.

### Comparative Example 1

A solar cell module K was manufactured as in Example 4 aside from the following changes. Two glass plates were used without masking. The silicone gel composition of Example 4 was knife coated to the entire one surface of each glass plate and heated in an oven at 120° C. for 10 minutes to form a cured silicone gel coating having a thickness of 500 μm. No seal member like frame molding was placed.

### Comparative Example 2

Two transparent films of EVA (ethylene-vinyl acetate copolymer with a vinyl acetate content of 28%) having a thickness of 500 μm were used. According to the prior art method, a silicon solar cell component was sandwiched between two glass plates via the EVA films. Using a vacuum laminator, the assembly was heated in vacuum at 120° C. for 30 minutes for melting and pressure bonding the EVA films. A solar cell module L was manufactured.

The solar modules A to L thus manufactured were evaluated by a crack test and an accelerated aging test.

### (1) Crack Evaluation of Solar Cell Component (Initial Crack Count)

This test is to examine whether or not cracks formed in the solar cell component in the solar module as completed. Evaluation was made by typical techniques, visual observation and electroluminescence (EL) imaging. Specifically, cracks in the solar cell component were detected by visual observation. When a forward current was conducted to the solar module under test, the solar module emitted light as an EL light source. The number of non-emissive spots was counted as cracks.

### (2) Accelerated Aging Test

The solar cell module was subjected to a pressure cooker test (PCT) as the accelerated aging (or severe degradation) test. The test was conducted under conditions: temperature 125° C., humidity 95%, and 2.1 atmospheres for 100 hours. After the test, cracks were evaluated or counted by EL imaging, tab wires were inspected for corrosion by visual observation, and the moisture ingress into the module was inspected by visual observation.

The test results are shown in Table 1.

TABLE 1

| | | | | | | | Test results | | | |
|---|---|---|---|---|---|---|---|---|---|---|
| | | | Cured Silicone coating | | | | Initial | | | |
| | | | Sunlight-incident | | | | crack | After PCT test | | |
| | | | side | | Back side | | count | | Tab | |
| | | | | Thickness | | Thickness | (by EL | Crack | wire | Moisture |
| | | Module | Penetration | (μm) | Penetration | (μm) | imaging) | count | corrosion | ingress |
| Example | 1 | A | 70 | 200 | 70 | 200 | 0 | 1 | Not | Not |
| | | | | | | | | | detected | detected |
| | 2 | B | 70 | 500 | 70 | 500 | 0 | 0 | Not | Not |
| | | | | | | | | | detected | detected |
| | 3 | C | 70 | 800 | 70 | 800 | 0 | 0 | Not | Not |
| | | | | | | | | | detected | detected |
| | 4 | D | 40 | 200 | 40 | 200 | 1 | 2 | Not | Not |
| | | | | | | | | | detected | detected |
| | 5 | E | 40 | 500 | 40 | 500 | 0 | 0 | Not | Not |
| | | | | | | | | | detected | detected |
| | 6 | F | 40 | 800 | 40 | 800 | 0 | 0 | Not | Not |
| | | | | | | | | | detected | detected |
| | 7 | G | 120 | 200 | 120 | 200 | 1 | 2 | Not | Not |
| | | | | | | | | | detected | detected |
| | 8 | H | 120 | 500 | 120 | 500 | 1 | 1 | Not | Not |
| | | | | | | | | | detected | detected |
| | 9 | I | 120 | 800 | 120 | 800 | 0 | 0 | Not | Not |
| | | | | | | | | | detected | detected |
| | 10 | J | 70 | 500 | 40 | 500 | 0 | 0 | Not | Not |
| | | | | | | | | | detected | detected |
| Comparative | 1 | K | 40 | 500 | 40 | 500 | 0 | 5 | Detected | Detected |

| | | | | | | | | |
|---|---|---|---|---|---|---|---|---|
| Example | 2 | L | EVA film/500 μm | EVA film/500 μm | 2 | 3 | Detected | Detected |

While the invention has been illustrated and described in typical embodiments, it is not intended to be limited to the details shown, since various modifications and substitutions can be made without departing in any way from the spirit of the present invention. As such, further modifications and equivalents of the invention herein disclosed may occur to persons skilled in the art using no more than routine experimentation, and all such modifications and equivalents are believed to be within the spirit and scope of the invention as defined by the following claims.

Japanese Patent Application No. 2012-121475 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A method for manufacturing a solar cell module by encapsulating a semiconductor substrate-based solar cell component between two panels, comprising the steps of:
(i) coating a curable silicone gel composition onto one surface of each panel except a peripheral region thereof and curing the composition to form a cured silicone gel coating having a penetration of 30 to 200 as measured according to JIS K2220,
(ii) providing a seal member on the peripheral region of the one surface of one panel where the cured silicone gel coating is not formed, said seal member being made of a butyl rubber-based thermoplastic sealing material and being thicker than the cured silicone gel coating, and placing the solar cell component on the cured silicone gel coating,
(iii) placing the other panel on the one panel while the cured silicone gel coating on the other panel facing the solar cell component so that the seal member abuts against the peripheral region of the one surface of the other panel where the cured silicone gel coating is not formed, and the solar cell component is sandwiched between the cured silicone gel coatings on the panels, and
(iv) pressing the two panels together while heating in vacuum for thereby encapsulating the solar cell component.

2. The method of claim 1 wherein the curable silicone gel composition comprises
(A) 100 parts by weight of an organopolysiloxane containing at least one silicon-bonded alkenyl group per molecule, represented by the average compositional formula (1):
RₐR¹_{b}SiO_{(4-a-b)/2} (1)
wherein R is alkenyl, R¹ is a substituted or unsubstituted monovalent hydrocarbon group of 1 to 10 carbon atoms free of aliphatic unsaturation, a is a positive number of 0.0001 to 0.2, b is a positive number of 1.7 to 2.2, and the sum a+b is 1.9 to 2.4,
(B) an organohydrogenpolysiloxane containing at least two silicon-bonded hydrogen atoms per molecule, in such an amount as to give 0.3 to 2.5 moles of silicon-bonded hydrogen per mole of silicon-bonded alkenyl in component (A), and
(C) a catalytic amount of an addition reaction catalyst.

3. The method of claim 2 wherein the organohydrogenpolysiloxane (B) has an average degree of polymerization of 40 to 400.

4. The method of claim 1 wherein the cured silicone gel coating has a thickness of 200 to 1,000 μm.

5. The method of claim 1 wherein step (ii) includes pre-forming the seal member in tape or string form from the butyl rubber-based thermoplastic sealing material and extending the seal member on the peripheral region of the one surface of one panel where the cured silicone gel coating is not formed.

6. The method of claim 1 wherein step (iv) includes heating the panels at 100 to 150° C. in vacuum.

7. The method of claim 1 wherein step (iv) is carried out using a vacuum laminator.

8. The method of claim 1 wherein the two panels are colorless tempered glass plates.
